(19) United States
(12) Patent Application Publication
(10) Pub. No.: US 2012/0305934 A1
(43) Pub. Date: Dec. 6, 2012

(54) NITRIDE SEMICONDUCTOR LIGHT EMITTING ELEMENT AND METHOD FOR MANUFACTURING THE SAME

(75) Inventor: Mayuko FUDETA, Osaka-shi (JP)

(73) Assignee: Sharp Kabushiki Kaisha, Osaka-shi (JP)

(21) Appl. No.: 13/471,728

(22) Filed: May 15, 2012

(30) Foreign Application Priority Data
May 30, 2011 (JP) 2011-120063

(51) Int. Cl. H01L 33/32

(52) U.S. Cl. 257/76; 438/46; 257/E33.025

(57) ABSTRACT

A nitride semiconductor light emitting element has: a substrate for growth; an n-type nitride semiconductor layer formed on the substrate for growth; a light emitting layer formed on the n-type nitride semiconductor layer; and a p-type nitride semiconductor layer formed on the light emitting layer, wherein pipe holes are formed at a density of 5000 pipe holes/cm² or less, each of which extends substantially vertically from a surface of the n-type nitride semiconductor layer on the light emitting layer side toward the substrate and has a diameter of 2 to 200 nm.

This nonprovisional application is based on Japanese Patent Application No. 2011-120063 filed on May 30, 2011 with the Japan Patent Office, the entire contents of which are hereby incorporated by reference.

### BACKGROUND OF THE INVENTION

1. Field of the Invention

The present invention relates to a nitride semiconductor light emitting element and a method for manufacturing the same.

2. Description of the Background Art

In applications of a conventional nitride semiconductor light emitting element, even when the performance of the nitride semiconductor light emitting element such as light emission output, electrostatic withstand voltage and light emission wavelength was somewhat unstable, it did not create problems in the use of the nitride semiconductor light emitting element. However, when the nitride semiconductor light emitting element is used as a light source for a backlight of a liquid crystal television or an LED lighting system that has been rapidly spreading in recent years, the following problem arises: when an electrostatic breakdown occurs at one nitride semiconductor light emitting element, it is regarded as a failure of the entire product and the product is judged as a defective product. Therefore, all of the nitride semiconductor light emitting elements used in the light source for the backlight of the liquid crystal television must pass destructive inspection such as static electricity application test, and high electrostatic withstand voltage is essential.

For example, Japanese Patent Laying-Open No. 2005-260215 (referred to as “PTL 1” hereinafter) discloses a nitride semiconductor light emitting element for increasing the electrostatic withstand voltage. FIG. 9 is a schematic cross-sectional view showing a configuration of the nitride semiconductor light emitting element disclosed in PTL 1. As shown in FIG. 9, the nitride semiconductor light emitting element in PTL 1 has, between an n-side contact layer 4 and an active layer 11, at least a first n-side layer 5, a second n-side layer 6, a third n-side layer 7, and a fourth n-side layer 8 in order from the n-side contact layer 4 side. In the nitride semiconductor light emitting element in PTL 1, an n-type impurity is introduced into second n-side layer 6 and fourth n-side layer 8 such that n-type impurity concentrations of second n-side layer 6 and fourth n-side layer 8 are higher than n-type impurity concentrations of first n-side layer 5 and third n-side layer 7.

### SUMMARY OF THE INVENTION

In accordance with a manufacturing method in PTL 1, about 50000 nitride semiconductor light emitting elements were fabricated using a 4-inch substrate, and the static electricity application test was conducted on all of the nitride semiconductor light emitting elements. The test result is shown in FIG. 10. FIG. 10 is a graph showing a relationship between applied voltage at the time of occurrence of a breakdown when the static electricity application test is conducted on the nitride semiconductor light emitting elements in PTL 1, and the number of broken nitride semiconductor light emitting elements. The horizontal axis in FIG. 10 indicates applied voltage at the time of occurrence of a breakdown, and the vertical axis in FIG. 10 indicates the number of broken nitride semiconductor light emitting elements.

It can be seen from the graph in FIG. 10 that approximately 19000 nitride semiconductor light emitting elements that are not broken even when a voltage of −4000 V or higher is applied are fabricated in the manufacturing method in PTL 1. On the other hand, approximately 31000 nitride semiconductor light emitting elements that are broken at a low voltage of −200 V or lower are fabricated. As described above, when the nitride semiconductor light emitting elements are fabricated in accordance with the manufacturing method in PTL 1, the nitride semiconductor light emitting elements having excellent electrostatic withstand voltage are fabricated, whereas about half of the fabricated nitride semiconductor light emitting elements have low electrostatic withstand voltage.

The following is considered to be the reason why the property of the electrostatic withstand voltage varies as described above: uniform crystal growth of a nitride layer over the entire surface of a wafer is impossible and a crystal defect occurs partially in a plane of the wafer. In other words, when the wafer manufactured in accordance with the manufacturing method in PTL 1 is broken down into chips, chips that do not include the crystal defect have high electrostatic withstand voltage, whereas chips that include the crystal defect have low electrostatic withstand voltage. As a result, the nitride semiconductor light emitting elements having high electrostatic withstand voltage and the nitride semiconductor light emitting elements having low electrostatic withstand voltage are fabricated from the same wafer.

The case where the 4-inch substrate is used to manufacture the nitride semiconductor light emitting elements has been described above by way of example. When a large-diameter substrate such as, for example, a 6-inch substrate is used to manufacture the nitride semiconductor light emitting elements, about 130000 nitride semiconductor light emitting elements are manufactured from one substrate. However, about half of the nitride semiconductor light emitting elements have low electrostatic withstand voltage, and thus, the manufacturing yield of the nitride semiconductor light emitting elements is poor.

The present invention has been made to solve the aforementioned problem and an object of the present invention is to provide a nitride semiconductor light emitting element and a method for manufacturing the same, in which the nitride semiconductor light emitting element having high electrostatic withstand voltage can be manufactured with high yield.

How the aforementioned electrostatic breakdown occurs will be described. When a high electric field is applied in a direction opposite to a direction of a normal electric field applied to the nitride semiconductor light emitting element, a depletion layer extends to the n-type nitride semiconductor layer side because the active layer is an undoped layer or low-doped n-type layer. When a defect or the like through which a current easily flows is present in this depletion layer, the current concentrates on the defect and heat is generated, which leads to occurrence of the electrostatic breakdown.

The inventors of the present invention analyzed the electrostatically-broken nitride semiconductor light emitting element, and it became clear that there is a pipe hole having a diameter of approximately several nanometers in the n-type nitride semiconductor layer located below the breakdown position. Then, the nitride semiconductor light emitting element was cut in a plane including the pipe hole and a cross section thereof was observed by means of an STEM to check a relationship between the pipe hole and the breakdown position. FIG. 1 is an observation image obtained by observing, by means of the STEM, the cut surface when the nitride semiconductor light emitting element is cut in the plane including the pipe hole. FIG. 1 shows the pipe hole. A correlation between the pipe hole and a failure occurrence rate in the static electricity application test was examined, and it was found that a failure is more likely to occur in the static electricity application test as the density of the pipe holes is higher as shown in FIG. 2.

FIG. 2 is a graph showing a relationship between the density of the pipe holes and the failure occurrence rate. Based on the result shown in FIG. 2, it was found that a high electric field is not applied to the pipe holes as the density of the pipe holes is lower, and the depletion layer does not extend to the position where the pipe holes are located. As a result, the present invention was completed.

Specifically, a nitride semiconductor light emitting element according to the present invention has: a substrate for growth; an n-type nitride semiconductor layer formed on the substrate for growth; a light emitting layer formed on the n-type nitride semiconductor layer; and a p-type nitride semiconductor layer formed on the light emitting layer, wherein pipe holes are formed at a density of 5000 pipe holes/cm² or less, each of which extends substantially vertically from a surface of the n-type nitride semiconductor layer on the light emitting layer side toward the substrate and has a diameter of 2 to 200 nm.

Preferably, an n-type superlattice layer is further included between the n-type nitride semiconductor layer and the light emitting layer. Preferably, the n-type superlattice layer includes one or more layers having an n-type impurity concentration of 2×10¹⁷ cm⁻³ or more.

Preferably, the n-type nitride semiconductor layer is formed of a first n-type GaN layer and a second n-type GaN layer. Preferably, the second n-type GaN layer includes a low-doped layer having a low n-type impurity concentration and a highly-doped layer having a high n-type impurity concentration. Preferably, the n-type impurity concentration of the low-doped layer is lower than an n-type impurity concentration of the first n-type GaN layer.

Preferably, the n-type impurity concentration of the highly-doped layer is higher than the n-type impurity concentration of the first n-type GaN layer. Preferably, the substrate for growth is a substrate having a nitride semiconductor layer on a surface thereof or a nitride semiconductor substrate.

The present invention also relates to a method for manufacturing a nitride semiconductor light emitting element including the steps of: forming a first n-type GaN layer on a substrate for growth; forming a second n-type GaN layer on the first n-type GaN layer; forming a light emitting layer on the second n-type GaN layer; and forming a p-type nitride semiconductor layer on the light emitting layer, wherein a molar flow ratio (V/III) of an amount of an introduced group V material to an amount of an introduced group III material in the step of forming a second n-type GaN layer is lower than a molar flow ratio (V/III) of an amount of the introduced group V material to an amount of the introduced group III material in the step of forming a first n-type GaN layer.

Preferably, the molar flow ratio (V/III) of the amount of the introduced group V material to the amount of the introduced group III material in the step of forming a second n-type GaN layer is 300 or less.

Preferably, the molar flow ratio (V/III) of the amount of the introduced group V material to the amount of the introduced group III material in the step of forming a first n-type GaN layer is 300 or more.

Preferably, a step of forming an n-type superlattice layer on the second n-type GaN layer is included after the step of forming a second n-type GaN layer.

Preferably, a step of raising a temperature of the substrate for growth is included before the step of forming a first n-type GaN layer. Preferably, a flow rate of the group V material in the step of raising a temperature of the substrate for growth is the same as a flow rate of the group V material in the step of forming a first n-type GaN layer.

Preferably, in the step of forming a first n-type GaN layer and the step of forming a second n-type GaN layer, a gas is introduced at a flow velocity of 10 cm/second or higher and 300 cm/second or lower. Preferably, in the step of forming a second n-type GaN layer, the second n-type GaN layer is formed at a growth temperature of 900° C. or higher.

According to the present invention, the nitride semiconductor light emitting element having high electrostatic withstand voltage can be manufactured with high yield.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an observation image obtained by observing, by means of the STEM, a cut surface when a nitride semiconductor light emitting element is cut in a plane including a pipe hole.

FIG. 2 is a graph showing a relationship between a density of the pipe holes and a failure occurrence rate.

FIG. 3 is a cross-sectional view showing one example of a configuration of a nitride semiconductor light emitting element according to the present invention.

FIG. 4 is a flowchart showing a method for manufacturing the nitride semiconductor light emitting element according to the present invention in the order of steps.

FIG. 5 is a graph showing a comparison between the distribution of pipe density of a conventional nitride semiconductor light emitting element and the distribution of pipe density of the nitride semiconductor light emitting element according to the present invention.

FIG. 6 is an observation image obtained by observing, by means of the STEM, a cut surface when a nitride semiconductor light emitting element is cut in a plane including a pipe hole.

FIG. 7 is an observation image obtained by observing an upper surface of a large pit by means of an SEM.

FIG. 8 is an observation image obtained by observing a surface of a second n-type GaN layer by means of a microscope.

FIG. 9 is a schematic cross-sectional view showing a configuration of a nitride semiconductor light emitting element disclosed in PTL 1.

FIG. 10 is a graph showing a relationship between applied voltage at the time of occurrence of a breakdown when the static electricity application test is conducted on the nitride semiconductor light emitting elements in PTL 1, and the number of broken nitride semiconductor light emitting elements.

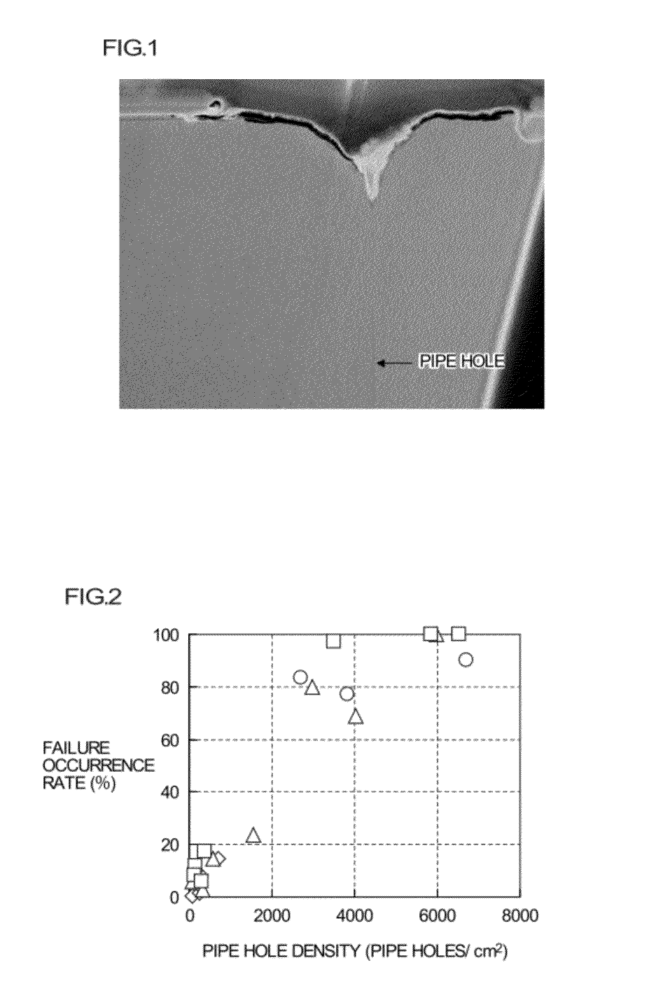

### DESCRIPTION OF THE PREFERRED EMBODIMENTS

A nitride semiconductor light emitting element according to the present invention will be described hereinafter.

<Nitride Semiconductor Light Emitting Element>

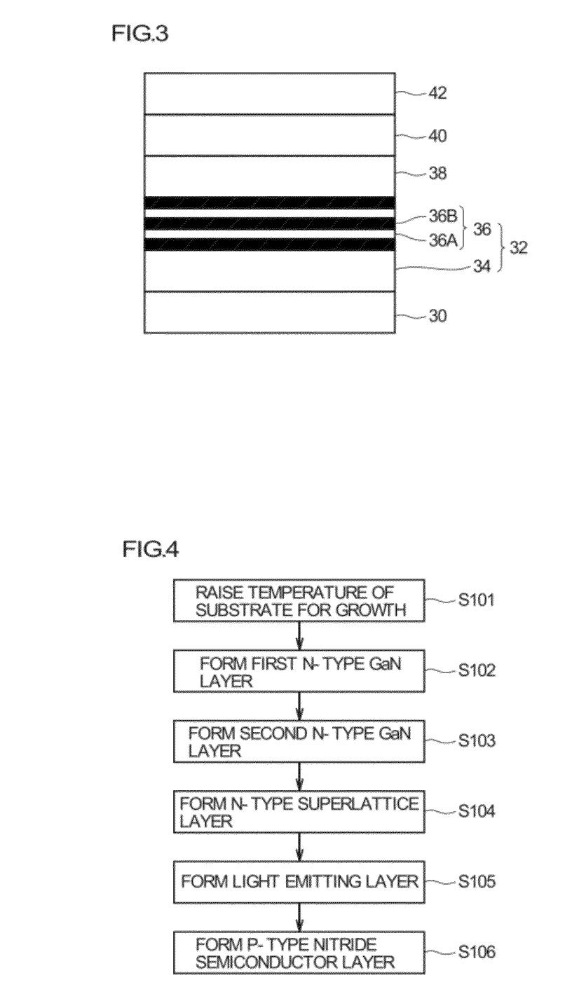

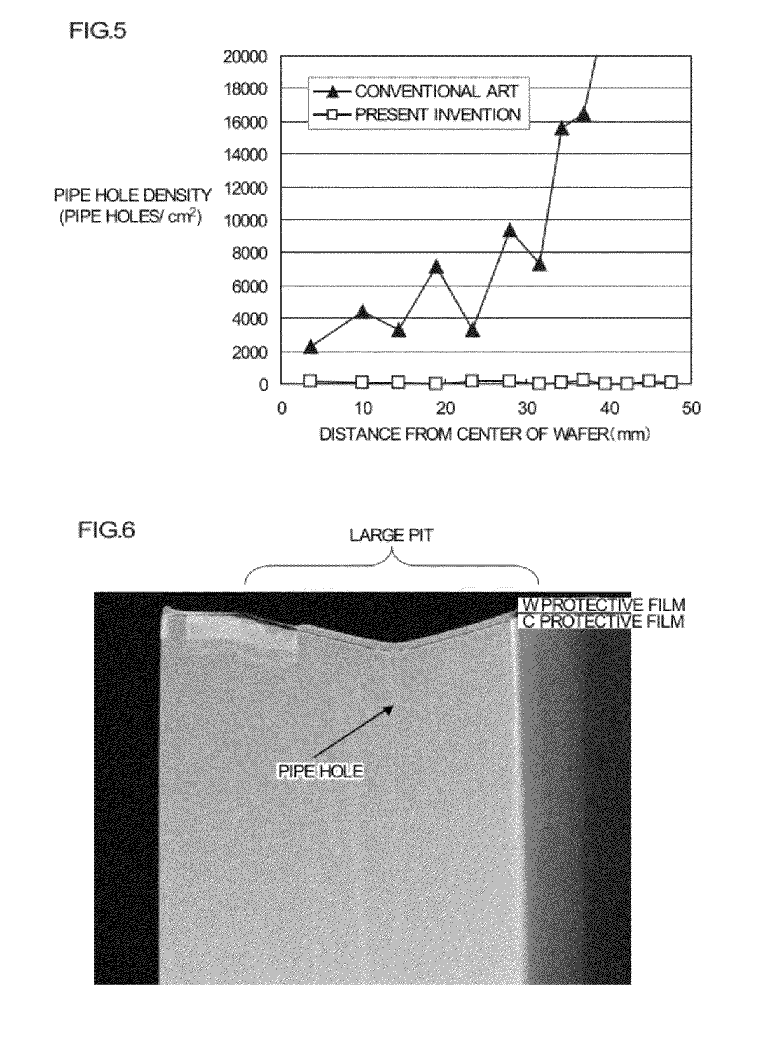

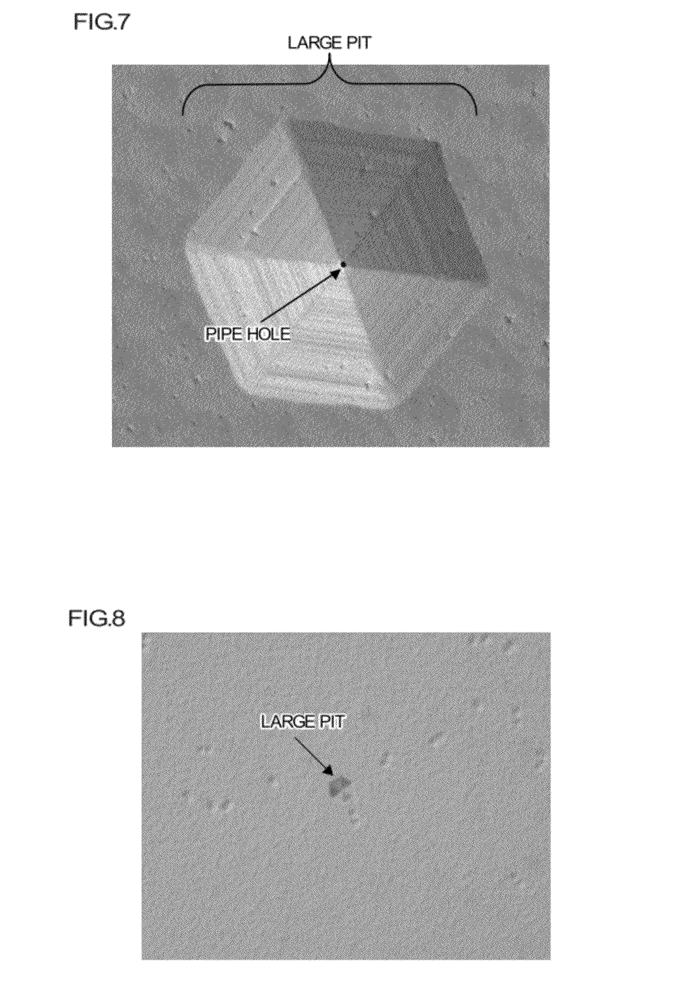

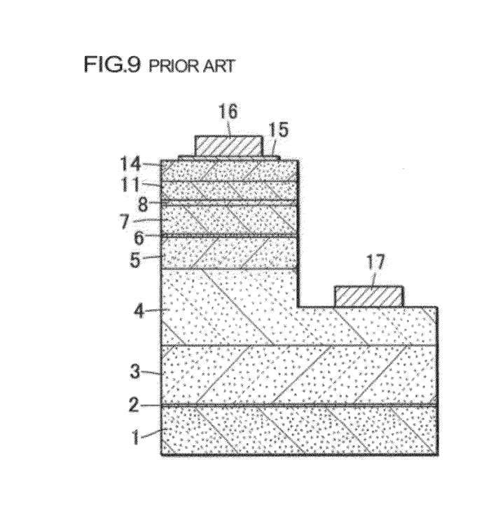

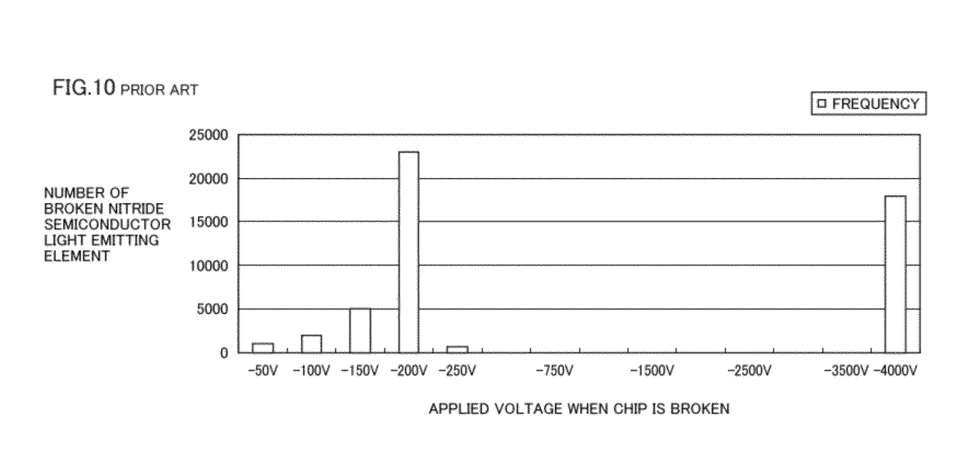

FIG. 3 is a cross-sectional view showing one example of a configuration of the nitride semiconductor light emitting element according to the present invention. The nitride semiconductor light emitting element shown in FIG. 3 has a substrate 30 for growth, an n-type nitride semiconductor layer 32 formed on substrate 30 for growth, a light emitting layer 40 formed on n-type nitride semiconductor layer 32, and a p-type nitride semiconductor layer 42 formed on light emitting layer 40. Pipe holes (see FIGS. 6 and 7) are formed at a density of 5000 pipe holes/cm² or less, each of which extends substantially vertically from a surface of n-type nitride semiconductor layer 32 on the light emitting layer 40 side (an upper surface of n-type nitride semiconductor layer 32 in FIG. 3) toward substrate 30 for growth and has a diameter of 2 to 200 nm. Since the density of the pipe holes is low as described above, the electrostatic breakdown is less likely to occur, and thus, the nitride semiconductor light emitting element having high electrostatic withstand voltage can be manufactured. In a nitride semiconductor light emitting element satisfying the aforementioned density of the pipe holes and having an area of, for example, 9.5×10⁻⁴ cm², the number of the pipe holes per one element is equal to or smaller than five. It is known that the electrostatic withstand voltage can be increased when the number of the pipe holes per one element is equal to or smaller than five. On the other hand, when the number of the pipe holes exceeds five, the electrostatic withstand voltage tends to decrease significantly. The aforementioned density of the pipe holes is preferably 3000 pipe holes/cm² or less. In this case, even in a large-size element like an element having an area of, for example, 1.6×10⁻³ cm², the number of the pipe holes per one element can be equal to or smaller than five. In an element having an area of 9.5×10⁻⁴ cm², the number of the pipe holes per one element is equal to or smaller than three, and thus, the electrostatic breakdown can be much less likely to occur. The aforementioned density of the pipe holes is more preferably 1000 pipe holes/cm² or less. In this case, even in a larger-size element like an element having an area of, for example, 5.0×10⁻³ cm², the number of the pipe holes per one element can be equal to or smaller than five. Smaller number of the pipe holes is preferable. However, elimination of the pipe holes (reducing the number of the pipe holes to zero) is considered to be almost impossible realistically.

<Substrate for Growth>

In the present invention, substrate 30 for growth is preferably a substrate having a nitride semiconductor layer on a surface thereof or a nitride semiconductor substrate. In this substrate 30 for growth, there is a tendency that the pipe holes are closed during crystal growth of the nitride semiconductor layer, as compared with a conventional substrate such as a sapphire substrate, a spinel substrate and an SiC substrate other than the nitride semiconductor substrate. Therefore, the number of the pipe holes present in substrate 30 for growth can be reduced. The substrate having a nitride semiconductor layer on a surface thereof can include, for example, a substrate obtained by processing a surface of a sapphire substrate to have protrusions and recesses, forming a buffer layer of AlN by a sputtering method on the surface of the sapphire substrate processed to have the protrusions and recesses, and forming a GaN layer on the buffer layer by an MOCVD method, an HYPE method or the like.

Since many pipe holes are present in the surface of aforementioned substrate 30 for growth, it is important to reduce the number of the pipe holes in substrate 30 for growth. By forming n-type nitride semiconductor layer 32 and the like on substrate 30 for growth having a small number of the pipe holes, the number of the pipe holes formed in n-type nitride semiconductor layer 32 can be further reduced. Therefore, a failure resulting from the electrostatic withstand voltage and a failure resulting from reverse leakage can be suppressed, and the manufacturing yield of the nitride semiconductor light emitting element can be increased.

A substrate obtained by processing a surface on the nitride semiconductor layer side, of a front side and a rear side of a sapphire substrate, to have protrusions and recesses is preferably used as aforementioned substrate 30 for growth. Furthermore, a substrate obtained by forming a buffer layer made of AlN on a surface of a sapphire substrate processed to have protrusions and recesses, and forming an undoped GaN layer and an n-type GaN layer on the buffer layer is preferably used as substrate 30 for growth.

<N-Type Nitride Semiconductor Layer>

In the present invention, n-type nitride semiconductor layer 32 is preferably formed of a first n-type GaN layer 34 and a second n-type GaN layer 36.

The doping concentration of aforementioned first n-type GaN layer 34 is preferably 1×10¹⁸ to 2×10¹⁹ cm⁻³, and more preferably 3×10¹⁸ to 9×10¹⁸ cm⁻³. First n-type GaN layer 34 preferably has a thickness of, for example, 0.3 to 3 μm.

Second n-type GaN layer 36 includes a low-doped layer 36A having a low n-type impurity concentration and a highly-doped layer 36B having a high n-type impurity concentration. The n-type impurity concentration of low-doped layer 36A is preferably lower than the n-type impurity concentration of first n-type GaN layer 34. Since second n-type GaN layer 36 includes highly-doped layer 36B and low-doped layer 36A as described above, there is a tendency that the pipe holes are closed at an interface where the doping concentration changes from high to low. Therefore, the number of the pipe holes can be reduced and the electrostatic withstand voltage can be increased.

The doping concentration of aforementioned second n-type GaN layer 36 is preferably 3×10¹⁷ to 5×10¹⁸ cm⁻³, and more preferably 5×10¹⁷ to 1×10¹⁸ cm⁻³. When second n-type GaN layer 36 is formed by stacking a plurality of layers, the doping concentration of second n-type GaN layer 36 is calculated based on an average value of the doping concentrations of the respective layers.

Aforementioned second n-type GaN layer 36 is preferably configured by forming highly-doped layers 36B and low-doped layers 36A alternately and repeatedly. Since second n-type GaN layer 36 is provided with a plurality of interfaces where the doping concentration changes from high to low as described above, the pipe holes can be closed at these interfaces, and thus, the number of the pipe holes can be reduced. If the second n-type GaN layer does not include the highly-doped layer and is formed only of the low-doped layer, electrons are not sufficiently injected into an active layer (light emitting layer) when a current is passed in the forward direction of a light emitting diode. Therefore, an overflow occurs at the holes, which leads to decrease in light emission intensity.

The n-type impurity concentration of highly-doped layer 36B is preferably higher than the n-type impurity concentration of first n-type GaN layer 34. Since highly-doped layer 36B having a higher concentration than that of first n-type GaN layer 34 is formed on the side close to the active layer (light emitting layer 40) as described above, an overflow is less likely to occur at the holes and high light emission intensity can be obtained at a temperature higher than the room temperature in the actual use environment. Therefore, optical output can be enhanced.

The n-type impurity concentration of aforementioned highly-doped layer 36B is preferably 1×10¹⁸ to 3×10¹⁹ cm⁻³, and more preferably 6×10¹⁸ to 2×10¹⁹ cm⁻³. The n-type impurity concentration of low-doped layer 36A is preferably 1×10¹⁶ to 1×10¹⁸ cm⁻³, and more preferably 1×10¹⁶ to 5×10¹⁷ cm⁻³. Highly-doped layer 36B preferably has a thickness of 3 to 300 nm, and low-doped layer 36A preferably has a thickness of 50 to 500 nm.

<N-Type Superlattice Layer>

In the present invention, an n-type superlattice layer 38 is preferably included between n-type nitride semiconductor layer 32 and light emitting layer 40. N-type superlattice layer 38 preferably includes one or more layers having an n-type impurity concentration of 2×10¹⁷ cm⁻³ or more. Since n-type superlattice layer 38 includes one or more layers having such an impurity concentration, a depletion layer in the active layer (light emitting layer 40) does not extend to second n-type GaN layer 36 even when a high electric field resulting from reverse static electricity is applied. Therefore, the high electric field is not easily applied to the pipe holes present in second n-type GaN layer 36, and the electrostatic breakdown is less likely to occur. The aforementioned layer having an n-type impurity concentration of 2×10¹⁷ cm⁻³ or more is more preferably a layer having an n-type impurity concentration of 6×10¹⁷ cm⁻³ or more, and further preferably a layer having an n-type impurity concentration of 9×10¹⁷ cm⁻³ or more. Aforementioned n-type superlattice layer 38 is preferably formed by stacking Si-doped GaN layers and undoped InGaN layers alternately and periodically. Since the layers having different n-type impurity concentrations are stacked alternately as described above, growth of the depletion layer in light emitting layer 40 can be stopped at n-type superlattice layer 38. Conventionally known layers and electrodes can be used as light emitting layer 40, p-type nitride semiconductor layer 42 and an electrode (not shown).

<Pipe Hole>

The aforementioned density of the pipe holes is calculated as follows. First, the electrode of the nitride semiconductor light emitting element is removed with a chemical solution such as acid, and thereafter, p-type nitride semiconductor layer 42, the active layer (light emitting layer 40) and n-type superlattice layer 38 are removed by dry etching to expose second n-type GaN layer 36. Then, by etching the exposed surface of second n-type GaN layer 36 with a mixed solution of sulfuric acid and phosphoric acid, large pits and small pits are formed. The large pits are formed due to the pipe holes, and the small pits are formed due to spiral dislocation or mixed dislocation.

The pipe holes cannot be observed by means of an optical microscope, whereas the large pits are easily observed by means of the optical microscope. Since the number of the large pits is the same as the number of the pipe holes, the number of the pipe holes can be counted by counting the number of the large pits. In this manner, the density of the pipe holes is calculated.

In the aforementioned mixed solution used for etching, a mixing ratio (volume ratio) of sulfuric acid and phosphoric acid is preferably 3:1. However, the mixing ratio of sulfuric acid and phosphoric acid is not limited only to the aforementioned mixing ratio. The mixing ratio of sulfuric acid and phosphoric acid is not particularly limited as long as the large pits and the small pits are formed to such an extent that the large pits can be distinguished from the small pits. The temperature of the etchant is preferably set to 250° C. or higher. As a result, the large pits and the small pits can be fabricated by short-time etching, and thus, this etchant can be suitably used in a production site.

<Method for Manufacturing Nitride Semiconductor Light Emitting Element>

FIG. 4 is a flowchart showing a method for manufacturing the nitride semiconductor light emitting element according to the present invention in the order of steps. The nitride semiconductor light emitting element according to the present invention as shown in FIG. 3 is preferably manufactured in accordance with the method shown in FIG. 4. The method for manufacturing the nitride semiconductor light emitting element shown in FIG. 4 includes a step S102 of forming first n-type GaN layer 34 on substrate 30 for growth, a step S103 of forming second n-type GaN layer 36 on first n-type GaN layer 34, a step S105 of forming light emitting layer 40 on second n-type GaN layer 36, and a step S106 of forming p-type nitride semiconductor layer 42 on light emitting layer 40. A molar flow ratio (V/III) of an amount of an introduced group V material to an amount of an introduced group III material in step S103 of forming second n-type GaN layer 36 is lower than a molar flow ratio (V/III) of an amount of the introduced group V material to an amount of the introduced group III material in step S102 of forming first n-type GaN layer 34. By controlling the molar flow ratio (V/III) when first and second n-type GaN layers 34 and 36 are formed as described above, the pipe holes can be closed during formation of the layers, and thus, the ratio of the nitride semiconductor light emitting elements that are judged to be excellent in the static electricity application test can be raised. In other words, the manufacturing yield of the nitride semiconductor light emitting element having a high electrostatic withstand voltage can be increased.

<Step S101 of Raising Temperature of Substrate for Growth>

First, the temperature of substrate 30 for growth is raised to the below-described temperature when first n-type GaN layer 34 is formed (e.g., approximately 1030° C.). During this time, before the temperature of substrate 30 for growth exceeds 700° C., a group V material gas is preferably supplied at a flow rate that is the same as a flow rate when first n-type GaN layer 34 is grown. Since the group V material gas is fed while raising the temperature of substrate 30 for growth as described above, a defect is less likely to occur in first n-type GaN layer 34.

When the aforementioned flow rate of the group V material gas during raising the temperature of the substrate for growth is different from the flow rate of the group V material gas when the first n-type GaN layer is grown, there is a disadvantage that the flow rate of the group V material gas is unstable when the flow rate is changed. In addition, the change in flow rate leads to a change in surface temperature of the substrate for growth. Therefore, it is not preferable that the flow rate of the group V material gas during raising the temperature of the substrate for growth is different from the flow rate of the group V material gas when the first n-type GaN layer is grown.

<Step S102 of Forming First N-Type GaN Layer>

Next, first n-type GaN layer 34 is formed on substrate 30 for growth. When first n-type GaN layer 34 is formed, the molar flow ratio (V/III) of the amount of the introduced group V material to the amount of the introduced group III material is preferably 300 or more. As a result, occurrence of a defect formed in first n-type GaN layer 34 during raising the temperature can be suppressed. The aforementioned molar flow ratio (V/III) of the amount of the introduced group V material to the amount of the introduced group III material is preferably 300 or more and 2000 or less, and more preferably 400 or more and 1000 or less.

If the aforementioned molar flow ratio (V/III) is less than 300, a V-shaped pit is formed from an interface when the first n-type GaN layer starts to grow. Therefore, the molar flow ratio of less than 300 is not preferable. If the molar flow ratio (V/III) exceeds 1000, reaction of the group V material and the group III material in the gas phase becomes large and the crystal quality may deteriorate. Therefore, the molar flow ratio exceeding 1000 is not preferable. The growth velocity when the first n-type GaN layer is formed is preferably set to, for example, 2 μm/h, and the growth temperature is preferably set to approximately 1030° C.

In step S102 of forming first n-type GaN layer 34, the gas is preferably introduced at a flow velocity of 10 cm/second or higher and 300 cm/second or lower. Since the gas is introduced at such a flow velocity, a tendency that the pipe holes are likely to be generated in the outer circumference of the wafer can be improved and the number of the pipe holes can be reduced in the entire surface of the wafer. If the flow velocity of the gas is lower than 10 cm/second, the pipe holes are likely to be generated in the outer circumferential portion of the wafer. If the flow velocity of the gas exceeds 300 cm/second, the surface temperature of the wafer decreases due to an excessive amount of the gas, and the crystal quality deteriorates and the light emission efficiency decreases, similarly to the case where the growth temperature is decreased. “Gas” herein includes a carrier gas, in addition to the group III material gas and the group V material gas.

FIG. 5 is a graph showing a comparison between the distribution of pipe density of a conventional nitride semiconductor light emitting element and the distribution of pipe density of the nitride semiconductor light emitting element according to the present invention. As shown in FIG. 5, it can be seen that the pipe density is almost uniform regardless of a distance from the center of the wafer in the nitride semiconductor light emitting element according to the present invention, whereas the pipe density is higher as a distance from the center of the wafer increases in the conventional nitride semiconductor light emitting element. Therefore, it is clear that the pipe density is low on the entire surface of the wafer in the nitride semiconductor light emitting element according to the present invention.

<Step S103 of Forming Second N-Type GaN Layer>

Next, second n-type GaN layer 36 is formed on first n-type GaN layer 34. When second n-type GaN layer 36 is formed, the molar flow ratio (V/III) of the amount of the introduced group V material to the amount of the introduced group III material is preferably 300 or less. As a result, group III atoms on the surface of the wafer migrate before combining with group V atoms, and are likely to close the pipe holes. Therefore, the number of the pipe holes can be reduced. The molar flow ratio (V/III) of the amount of the introduced group V material to the amount of the introduced group III material is preferably 50 or more and 300 or less, and more preferably 70 or more and 300 or less. If the aforementioned molar flow ratio (V/III) exceeds 300, the group III atoms are less likely to migrate and to close the pipe holes. Therefore, the molar flow ratio exceeding 300 is not preferable.

In step S103 of forming second n-type GaN layer 36 as well, the gas is preferably introduced at a flow velocity of 10 cm/second or higher and 300 cm/second or lower, similarly to step S102 of forming first n-type GaN layer 34. Since the gas is introduced at such a flow velocity, a tendency that the pipe holes are likely to be generated in the outer circumference of the wafer can be improved and the number of the pipe holes can be reduced in the entire surface of the wafer. If the flow velocity of the gas is lower than 10 cm/second, the pipe holes are likely to be generated in the outer circumferential portion of the wafer. If the flow velocity of the gas exceeds 300 cm/second, the surface temperature of the wafer decreases due to an excessive amount of the gas, and the crystal quality deteriorates and the light emission efficiency decreases, similarly to the case where the growth temperature is decreased. “Gas” herein includes a carrier gas, in addition to the group III material gas and the group V material gas.

In addition, in step S103 of forming second n-type GaN layer 36, second n-type GaN layer 36 is preferably formed at a growth temperature of 900° C. or higher. Since second n-type GaN layer 36 is formed at such a growth temperature, migration of the group III material is promoted, and thus, the group III material is likely to close the pipe holes.

Second n-type GaN layer 36 is preferably formed by stacking a plurality of layers having different n-type impurity concentrations. In order to achieve these plurality of layers, an amount of the introduced n-type impurity is preferably changed as appropriate.

<Step S104 of Forming N-Type Superlattice Layer>

A step S104 of forming n-type superlattice layer 38 is preferably included after aforementioned step S103 of forming second n-type GaN layer 36. Since n-type superlattice layer 38 is formed on second n-type GaN layer 36 as described above, the depletion layer does not extend only to n-type superlattice layer 38 and further extension of the depletion layer can be prevented even when a high electric field is applied to the nitride semiconductor light emitting element in the reverse direction. Therefore, the electrostatic breakdown can be less likely to occur.

<Steps S105 and S106 of Forming Light Emitting Layer and P-Type Nitride Semiconductor Layer>

Light emitting layer 40 and p-type nitride semiconductor layer 42 can be manufactured in accordance with a conventionally known manufacturing method. The electrode is preferably a transparent electrode made of ITO or a bonding pad electrode made of Au, and is preferably fabricated in accordance with a general method. By performing the aforementioned steps, the nitride semiconductor light emitting element according to the present invention can be manufactured.

The present invention will be described hereinafter in more detail with reference to Examples, although the present invention is not limited to these Examples.

### Example 1

In the present example, a substrate for growth was used, which was obtained by forming a 30-nm-thick buffer layer that was formed by sputtering and was made of AlN, on a 4-inch sapphire substrate having protrusions and recesses on a surface thereof, and forming a 4-μm-thick undoped GaN layer and a 2-μm-thick n-type GaN layer on the buffer layer by the MOCVD method.

(Step of Raising Temperature of Substrate for Growth)

First, the substrate for growth was placed in an MOCVD apparatus and the temperature within the apparatus was raised. When the temperature of the substrate for growth reached 600° C., NH₃ was supplied at a flow rate that was the same as a flow rate when a below-described first n-type GaN layer was grown, and the temperature of the substrate for growth was raised to 1030° C.

(Step of Forming First N-Type GaN Layer)

Then, NH₃ serving as a group V material and TMG serving as a group III material were introduced at a flow velocity of 17 cm/second such that a molar ratio (V/III) thereof was 580, and the first n-type GaN layer having a thickness of 1 μm was grown on the substrate for growth at a growth velocity of 2 μm/h. Thus, the first n-type GaN layer having a doping concentration of 6×10¹⁸ cm⁻³ was fabricated.

(Step of Forming Second N-Type GaN Layer)

Next, the flow rate of NH₃ was reduced such that the molar ratio (V/III) of the group V material and the group III material was 290, and the gas was introduced at a flow velocity of 17 cm/second, and a second n-type GaN layer formed of five GaN layers having different doping concentrations was grown, with the temperature maintained at 1030° C. This second n-type GaN layer was obtained by growing, in order from the substrate side, a GaN layer having a doping concentration of 1×10¹⁸ cm⁻³ and having a thickness of 20 nm, a GaN layer having a doping concentration of 2×10¹⁷ cm⁻³ and having a thickness of 100 nm, a GaN layer having a doping concentration of 1×10¹⁸ cm⁻³ and having a thickness of 50 nm, a GaN layer having a doping concentration of 2×10¹⁷ cm⁻³ and having a thickness of 150 nm, and a GaN layer having a doping concentration of 9×10¹⁸ cm⁻³ and having a thickness of 15 nm.

(Step of Forming N-Type Superlattice Layer)

Next, the temperature was lowered to 760° C. to start growth of an n-type superlattice layer. This n-type superlattice layer was obtained by alternately forming 10 GaN layers, each of which was doped with Si at a concentration of 8×10¹⁷ cm⁻³ and had a thickness of 2.5 nm, and 10 undoped InGaN layers, each of which had a thickness of 2.5 nm. In the n-type superlattice layer thus formed, an average doping concentration of Si was about 4×10¹⁷ cm⁻³.

(Steps of Forming Light Emitting Layer and P-Type Nitride Semiconductor Layer)

Next, the temperature was lowered to 740° C. and a light emitting layer was grown on the n-type superlattice layer. Thereafter, a p-type nitride semiconductor layer was grown in accordance with a general method. As an electrode, a transparent electrode made of ITO, a bonding pad electrode made of Au, or the like was formed in accordance with a general method. A 4-inch wafer thus fabricated was divided into chips such that an area per one chip was about 1.5×10⁻³ cm⁻³. Thus, about 50000 nitride semiconductor light emitting elements were fabricated.

The number of pipe holes formed in the second n-type GaN layer of the nitride semiconductor light emitting element fabricated as described above was measured. The result was 300 pipe holes/cm². This means that 0.45 pipe holes per one nitride semiconductor light emitting element are present, i.e., one pipe hole per two nitride semiconductor light emitting elements is present.

The aforementioned number of the pipe holes was measured as follows. First, the electrode was removed with a chemical solution such as acid, and thereafter, the p-type nitride semiconductor layer, the active layer (light emitting layer) and the n-type superlattice layer were removed by dry etching to expose the second n-type GaN layer. Then, using, as an etchant, a mixed solution obtained by mixing sulfuric acid and phosphoric acid at a ratio (volume ratio) of 3:1, the etchant was heated to 250° C. and the exposed surface of the second n-type GaN layer was etched for 60 minutes.

As a result of the aforementioned etching process, a large pit having a diameter of about 5 μm or more and a small pit having a diameter of approximately 2 to 3 μm were formed on the surface of the second n-type GaN layer. An upper surface of this large pit was observed by means of the scanning electron microscope (SEM), and a cut surface when the nitride semiconductor light emitting element was cut in a plane including the large pit was observed by means of the scanning transmission electron microscope (STEM). FIG. 6 is an observation image obtained by observing, by means of the STEM, the cut surface when the nitride semiconductor light emitting element is cut in the plane including the pipe hole. FIG. 7 is an observation image obtained by observing the upper surface of the large pit by means of the SEM.

Based on the image of the cross section of the large pit in FIG. 6 and the image of the upper surface of the large pit in FIG. 7, it can be seen that the large pit is formed with the pipe hole being the center. Furthermore, FIG. 8 is an observation image obtained by observing the surface of the second n-type GaN layer by means of the microscope. As shown in FIG. 8, by counting the number of the large pits by means of the microscope, the density of the pipe holes was calculated.

The static electricity application test, in which −1500 V was applied three times in accordance with a human body model, was conducted on the 50000 nitride semiconductor light emitting elements fabricated in the above. As a result, approximately 150 electrostatically-broken defective chips were formed, which corresponded to only 3% of the whole. In the conventional method for manufacturing the nitride semiconductor light emitting element, defective chips manufactured in the static electricity application test were more than half of the whole. Therefore, it is clear that the manufacturing yield is greatly enhanced in the method for manufacturing the nitride semiconductor light emitting element according to the present invention, as compared with the conventional manufacturing method.

Although the embodiments and examples of the present invention have been described above, it is originally intended that the individual embodiments and examples are appropriately combined.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A nitride semiconductor light emitting element, comprising:
a substrate for growth;
an n-type nitride semiconductor layer formed on said substrate for growth;
a light emitting layer formed on said n-type nitride semiconductor layer; and
a p-type nitride semiconductor layer formed on said light emitting layer, wherein
pipe holes are formed at a density of 5000 pipe holes/cm² or less, each of which extends substantially vertically from a surface of said n-type nitride semiconductor layer on said light emitting layer side toward said substrate and has a diameter of 2 to 200 nm.

2. The nitride semiconductor light emitting element according to claim 1, further comprising
an n-type superlattice layer between said n-type nitride semiconductor layer and said light emitting layer, wherein
said n-type superlattice layer includes one or more layers having an n-type impurity concentration of 2×10¹⁷ cm⁻³ or more.

3. The nitride semiconductor light emitting element according to claim 1, wherein
said n-type nitride semiconductor layer is formed of a first n-type GaN layer and a second n-type GaN layer,
said second n-type GaN layer includes a low-doped layer having a low n-type impurity concentration and a highly-doped layer having a high n-type impurity concentration, and
the n-type impurity concentration of said low-doped layer is lower than an n-type impurity concentration of said first n-type GaN layer.

4. The nitride semiconductor light emitting element according to claim 3, wherein
the n-type impurity concentration of said highly-doped layer is higher than the n-type impurity concentration of said first n-type GaN layer.

5. The nitride semiconductor light emitting element according to claim 1, wherein
said substrate for growth is a substrate having a nitride semiconductor layer on a surface thereof or a nitride semiconductor substrate.

6. A method for manufacturing a nitride semiconductor light emitting element, comprising the steps of:
forming a first n-type GaN layer on a substrate for growth;
forming a second n-type GaN layer on said first n-type GaN layer;
forming a light emitting layer on said second n-type GaN layer; and
forming a p-type nitride semiconductor layer on said light emitting layer, wherein
a molar flow ratio (V/III) of an amount of an introduced group V material to an amount of an introduced group III material in said step of forming a second n-type GaN layer is lower than a molar flow ratio (V/III) of an amount of the introduced group V material to an amount of the introduced group III material in said step of forming a first n-type GaN layer.

7. The method for manufacturing a nitride semiconductor light emitting element according to claim 6, wherein
the molar flow ratio (V/III) of the amount of the introduced group V material to the amount of the introduced group III material in said step of forming a second n-type GaN layer is 300 or less.

8. The method for manufacturing a nitride semiconductor light emitting element according to claim 6, wherein
the molar flow ratio (V/III) of the amount of the introduced group V material to the amount of the introduced group III material in said step of forming a first n-type GaN layer is 300 or more.

9. The method for manufacturing a nitride semiconductor light emitting element according to claim 6, wherein
a step of forming an n-type superlattice layer on said second n-type GaN layer is included after said step of forming a second n-type GaN layer.

10. The method for manufacturing a nitride semiconductor light emitting element according to claim 6, wherein
a step of raising a temperature of said substrate for growth is included before said step of forming a first n-type GaN layer, and
a flow rate of the group V material in said step of raising a temperature of said substrate for growth is the same as a flow rate of the group V material in said step of forming a first n-type GaN layer.

11. The method for manufacturing a nitride semiconductor light emitting element according to claim 6, wherein
in said step of forming a first n-type GaN layer and said step of forming a second n-type GaN layer, a gas is introduced at a flow velocity of 10 cm/second or higher and 300 cm/second or lower.

12. The method for manufacturing a nitride semiconductor light emitting element according to claim 6, wherein
in said step of forming a second n-type GaN layer, said second n-type GaN layer is formed at a growth temperature of 900° C. or higher.
